(19) United States
(12) Patent Application Publication
(10) Pub. No.: US 2025/0170576 A1
(43) Pub. Date: May 29, 2025

(54) MICROFLUIDIC VALVE

(71) Applicant: Johnson Yiu-Nam Lau, Houston, TX (US)

(72) Inventors: Johnson Yiu-Nam LAU, Houston, TX (US); Yuk Lun Tsang, Hong Kong (CN); Lut Hey Chu, Hong Kong (CN); Lok Ting Lau, Hong Kong (CN)

(73) Assignee: EMERGING VIRAL DIAGNOSTICS (HK) LIMITED, Hong Kong (CN)

(21) Appl. No.: 18/832,481

(22) PCT Filed: Jan. 20, 2023
(86) PCT No.: PCT/US2023/011262

§ 371 Date: Jul. 23, 2024

Related U.S. Application Data
(60) Provisional application No. 63/302,125, filed on Jan. 23, 2022.

(51) Int. Cl. B01L 3/00; B81B 1/00; B81C 1/00; F16K 99/00

(52) U.S. Cl. CPC B01L 3/567; B81B 1/006; B81C 1/00119; F16K 99/0001; B01L 2200/027; B01L 2400/0638; B81B 2201/054; B81B 2203/0338; B81C 2201/034

(57) ABSTRACT

A microfluidic valve comprising an adhesive tape, an outlet disposed at one end of a first microfluidic channel, an inlet disposed at one end of a second microfluidic channel, wherein the inlet and the outlet are disposed in a proximity to each other, wherein the adhesive tape covers both the outlet and the inlet. A method of operating the microfluidic valve is also disclosed.

### FIELD OF INVENTION

This invention generally relates to microfluidics technology. More particularly, aspects of the invention relate to a valve. In particular, the invention relates to a fluid valve mechanism applied to microfluidic pathways.

### BACKGROUND

Microfluidic systems are typically used for handling small samples fluid for various purposes, from biochemical analysis to medical diagnostics. The microfluidic systems allow biochemical reactions to be carried out using a small amount of sample and reagent. Microfluidics system offer a significant cost savings in analysis and diagnostics of samples.

Microfluidic systems integrate assay operation on a single microfluidic chip. The assay operation usually involves moving the liquid through microchannels to different sectors inside a chip for sample pre-treatment, sample preparation and detection. Valves are installed on the microchannels to control the flow of the liquid.

These on-chip valves are usually placed or installed within the microfluidic channels. Installing valves within microfluidic channels requires high precision engineering, thereby increasing the manufacturing cost. Further, the additional valve structure within the microfluidic channels making the scaling, dimension and optimization of the microfluidic chip very difficult.

### SUMMARY

In view of the foregoing background, cost, size and reliability become the critical factors of valves for microfluidic systems.

To alleviate the issues, aspects of the invention provide a low cost microfluidic valve that is easy to manufacture. In addition, the microfluidic valve may be manufactured at low temperature. In some embodiments of the present invention, the microfluidic valve may be manufactured through thermal bonding of thermoplastics without using any adhesive materials. In a bonding process, temperature near or above the glass transition temperature (T_{g}) and sufficient pressure may be applied to the thermoplastic materials to soften the thermoplastic materials. The T_{g} depends on the type of thermoplastics; for example, T_{g} of Poly (methyl methacrylate) (PMMA) and polycarbonates (PC) may be around 100° C. and 145° C. respectively. Under the conditions of such temperature and pressure, deformation on the thermoplastic, e.g., microfluidic features, may occur and inconsistencies in the shape and/or volume of channels or chambers fabricated in a microfluidic device could be resulted. It therefore may be desirable to manufacture microfluidic components at a sufficiently low temperature to minimize the inconsistency between batches of microfluidic components including the microfluidic valves of the present invention. In some embodiments of the present invention, the microfluidic valve may be manufactured under a low temperature that is 20° C. or more below the T_{g} of the thermoplastic being used for the manufacture of the microfluidic device, thereby significantly may improve the consistence of the manufacture of the microfluidic valve and the microfluidic cartridge/device overall. Further, the microfluidic valve of the present invention may precisely control the flow of fluid within the microfluidic channels.

### BRIEF DESCRIPTION OF FIGURES

Persons of ordinary skill in the art may appreciate that elements in the figures are illustrated for simplicity and clarity so not all connections and options have been shown. For example, common but well-understood elements that are useful or necessary in a commercially feasible embodiment may often not be depicted in order to facilitate a less obstructed view of these various embodiments of the present disclosure. It may be further appreciated that certain actions and/or steps may be described or depicted in a particular order of occurrence while those skilled in the art may understand that such specificity with respect to sequence is not actually required. It may also be understood that the terms and expressions used herein may be defined with respect to their corresponding respective areas of inquiry and study except where specific meanings have otherwise been set forth herein.

FIG. 1 is a schematic view of an example of microfluidic valves on a microfluidic chip or cartridge according to one embodiment of the present invention.

FIG. 2 is a cross sectional view taken along A-A′ line of FIG. 1, showing one of the microfluidic valves on a microfluidic chip or cartridge according to one embodiment of the present invention.

FIG. 3 is a flow chart of a manufacturing process of a microfluidic valve according to an embodiment of the present invention.

FIG. 4 is a cross sectional view of a pressure sensitive adhesive tape of a valve before the peeling step according to an embodiment of the present invention.

FIG. 5 is a cross sectional view of a pressure sensitive adhesive tape of a valve after the peeling step according to an embodiment of the present invention.

FIG. 6 is a cross sectional view of a microfluidic valve after the assembling step according to an embodiment of the present invention.

FIG. 7 is a cross sectional view of a microfluidic valve in the close position according to one embodiment of the present invention.

FIG. 8 is a cross sectional view of a cross sectional view of a microfluidic valve in the open position according to one embodiment of the present invention.

FIG. 9 is a schematic view of an example of microfluidic valves on a microfluidic chip or cartridge according to another embodiment of the present invention.

### DETAILED DESCRIPTION

Embodiments may now be described more fully with reference to the accompanying drawings, which form a part hereof, and which show, by way of illustration, specific exemplary embodiments which may be practiced. These illustrations and exemplary embodiments may be presented with the understanding that the present disclosure is an exemplification of the principles of one or more embodiments and may not be intended to limit any one of the embodiments illustrated. Embodiments may be embodied in many different forms and should not be construed as limited to the embodiments set forth herein; rather, these embodiments are provided so that this disclosure may be thorough and complete, and may fully convey the scope of embodiments to those skilled in the art. Among other things, the present invention may be embodied as methods, systems, computer readable media, apparatuses, or devices. Accordingly, the present invention may take the form of an entirely hardware embodiment, an entirely software embodiment, or an embodiment combining software and hardware aspects. The following detailed description may, therefore, not to be taken in a limiting sense.

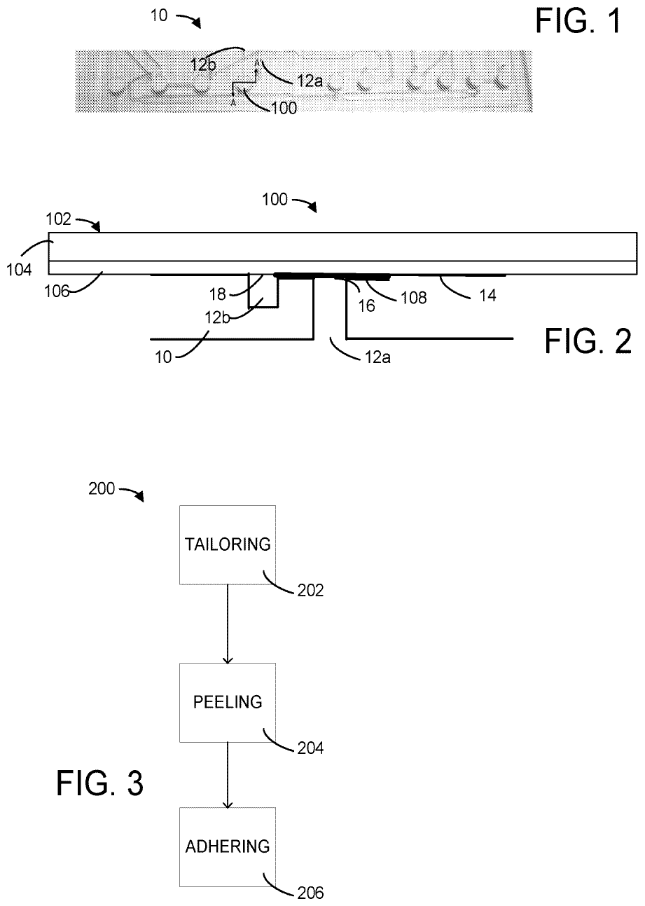

Referring to FIG. 1, a microfluidic chip or cartridge 10 may include a plurality of microfluidic channels 12 (e.g., 12a and 12b) and a microfluidic valve 100 disposed between the plurality of microfluidic channels 12. The microfluidic valve 100 may be in fluid communication with the plurality of microfluidic channels 12 and may be configured to control the flow of the fluid between/among the microfluidic channels 12. The microfluidic chip or cartridge 10 may include more than one microfluidic valves 100 disposed at different position to control the flow of fluid among the microfluidic channels 12.

Referring to FIG. 2, the microfluidic valve 100 may include a three-layer structure pressure sensitive tape 102 comprising a backing layer 104, adhesive layer 106 and a liner layer 108. In one embodiment, the adhesive layer 106 is sandwiched between the backing layer 104 and the liner layer 108. The tape 102 may be of materials that is bendable and/or flexible. The backing layer 104 may provide mechanical support to the tape 102. The adhesive layer 106 may be configured to bond the tape 102 to the surface of the microfluidic chip or cartridge 10. The liner layer 108 may be a layer that may avoid, alleviate, or prevents an exposure of the adhesive layer 106. In some embodiments, the liner layer 108 only may cover a predetermined portion of the adhesive layer 106 such that the liner layer 108 may cover an inlet 16 located at one end of a first microfluidic channel 12a but not an outlet 18 located at one end of a second microfluidic channel 12b when it is placed on the microfluidic chip of cartridge 10. In some embodiments, the liner layer 108 may only cover a determined portion of the adhesive layer such that the liner layer 108 only may cover the inlet 16 located at one end of a first microfluidic channel 12a and an outlet 18 located at one end of a second microfluidic channel 12b when it is placed on the microfluidic chip of cartridge 10. In some embodiments, the liner layer 108 may only cover a determined portion of the adhesive layer such that the liner layer 108 may only cover the inlet 16 and the surface of microfluidic chip or cartridge 10 that is in proximity to the inlet 16 when it is placed on the microfluidic chip of cartridge 10. In some embodiments, the liner layer 108 may only cover a determined portion of the adhesive layer such that the liner layer 108 may only cover both the inlet 16, the outlet 18 and the surface of microfluidic chip or cartridge 10 that is in proximity to the inlet 16 and the outlet 18 when it is placed on the microfluidic chip of cartridge 10.

The bottom of the adhesive layer 106 may include adhesive material configured to adhere or bond to a surface of a microfluidic chip or cartridge 10. In some embodiments, the adhesive material may be configured to adhere to a surface around a microfluidic channel 12 at adhesive area 14. In yet some embodiment, the adhesive materials may be configured to adhere to a surface around an inlet 16 located at one end of a first microfluidic channel 12a and an outlet 18 located at one end of a second microfluidic channel 12b, wherein the first microfluidic channel 12a and the second microfluidic channel 12b are in proximity to each other.

In some embodiments, the backing layer 104 is made of metal foil which may include aluminum foil, or polymer which may include polypropylene (PP), polyester, polyethylene terephthalate (PET), high-density polyethylene (HDPE), polyvinyl chloride (PVC), vinyl, polyethylene (PE), polyamide, nylon, polytetrafluoroethylene (PTFE), polyvinyl alcohol (PVA), polyurethane (PU) or polyvinyl fluoride (PVF).

In yet some embodiments, the adhesive layer 106 is made of adhesive materials including but not limited to acrylic, silicone and rubber/latex.

In yet some embodiments, the liner layer 108 is made of polymer which may include polypropylene (PP), polyester, polyethylene terephthalate (PET), high-density polyethylene (HDPE), polyvinyl chloride (PVC), vinyl, polyethylene (PE), polyamide, nylon, polytetrafluoroethylene (PTFE), polyvinyl alcohol (PVA), polyurethane (PU) or polyvinyl fluoride (PVF).

In some embodiments, the backing layer 104 of the present three-layer structure pressure sensitive tape may include a thickness of less than about 0.5 mm. However, it may still be strong enough to provide sufficient mechanical support to the tape. The backing layer 104 may possess desirable characteristics including without limitation being physically flexible or conformable, waterproof, chemical and solvent resistant, temperature resistant up to about 100° C. and low moisture absorption. In other embodiments, the temperature resistance may be between 50 to 80 degrees Celsius. As such, the backing layer may be durable and stable and may be suitable to long-term and continuous uses.

In some embodiments, the liner layer 108 of the present three-layer structure pressure sensitive tape may be a thickness of less than about 0.2 mm. The liner layer 108 may be possess desirable characteristics including without limitation being strong yet physically flexible or conformable, waterproof, chemical and solvent resistant, temperature resistant up to about 100° C., low moisture absorption and easily to be cut into various sizes. In other embodiments, the temperature resistance may be between 50 to 80 degrees Celsius. The liner layer 108 may also be non-sticky to the cartridge material and attachable to the adhesive layer.

In some embodiments, the adhesive layer 106 of the present three-layer structure pressure sensitive tape may exhibit strong bonding strength to the cartridge material and may be able to maintain its adhesive strength up to 100° C., thereby providing good adhesion between the microfluidic value and the cartridge even under high temperature. In other embodiments, the temperature resistance may be between 50 to 80 degrees Celsius.

Referring to FIG. 3, microfluidic valve's manufacturing process 200 comprises a tailoring step 202, peeling step 204 and adhering step 206. Referring to FIG. 4, the tailoring step 202 may include tailoring the tape 202 with a predetermined size and the shape to meet predetermined requirement. In some examples, the size may be larger than the cross sectional area of two microfluidic channels 12 disposing in a proximity to each other. In some examples, the shape may be in circle, rectangle, triangle or in any other shapes.

In the peeling step 204, a predetermined portion of the liner layer 108 may be preserved and the non-preserved portion may be removed from the tape 202 obtained from the tailoring step 202. Referring to FIG. 5, after the liner layer 108 may be removed, the adhesive layer 106 may be exposed, which may be adhered to the surface of the microfluidic chip or cartridge 10. In some embodiments, the size and shape of the preserved portion may be larger than the cross sectional area of the inlet 16 but may not cover the outlet 18 disposed in a proximity to the inlet 16. In yet some embodiments, the size and shape of the preserved portion may cover both inlet 16 and outlet 18. In some embodiments, the non-removed liner layer 108 may be in any shape, for example, circle, rectangle, triangle or in any other shapes.

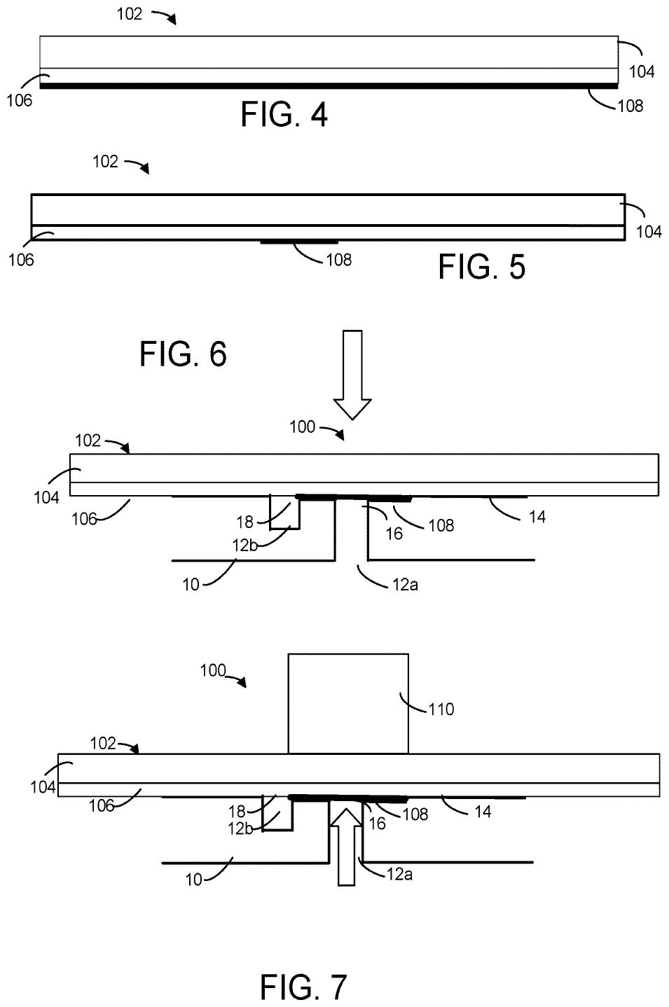

In the adhering step 206, referring to FIG. 6, the tape 202 from the peeling step 204 may be adhered to the surface of the microfluidic chip or cartridge 10 at the adhesive area 14 around the inlet 16 and the outlet 18.

Now refer to the operation of the microfluidic valve 100 of the present invention. FIG. 7 may illustrate the microfluidic valve 100 in a closed position. The microfluidic valve 100 may further include an actuator 110. The actuator 110 is configured to move towards or away from the inlet 16 and the outlet 18. In some embodiments, the actuator 110 may be moved in vertically, diagonally or horizontally. In some embodiments, the actuator 110 may be moved or controlled by any mechanical structures for moving it towards or away from the inlet 16 and the outlet 18. In yet some embodiments, the actuator 110 may be moved toward to the inlet 16 by spring force or gravity only and move away from the inlet 16 when a predetermined of pressure may be reached at inlet 16.

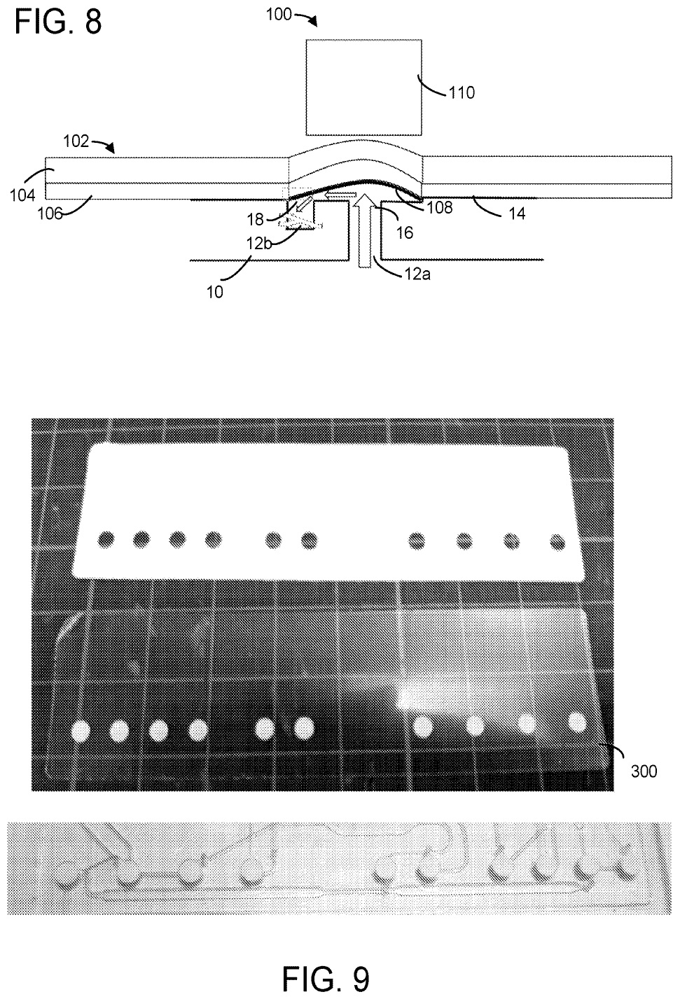

Referring to FIG. 8, the microfluidic valve 100 in the open position. At this open position, the actuator 110 may be moved away from the inlet 16 such that the predetermined portion of the tape 202 in the proximity of the inlet 16 and outlet 18 may be pushed away from the inlet 16 and outlet 18 due to the pressure built up at the inlet 16 as the fluid flows to the inlet 16. A pocket may be formed at such portion such that the inlet 16 may be in fluid communication with the outlet 18. The microfluidic channel 12a and the microfluidic channel 12b may be in fluid communication through the pocket volume among the first microfluidic channel 12a and the second microfluidic channel 12b and the tape 202. As such, the fluid may flow freely from the microfluidic channel 12a to microfluidic channel 12b.

In some embodiments, the microfluidic valve 100 may not include the actuator 110.

Referring to FIG. 9, multiple tapes 102 may be placed on the surface of the microfluidic chip or cartridge 10. As such, a plurality of microfluidic valves 100 may be easily installed on the plurality of inlets 16 and outlets 18.

The above description is illustrative and is not restrictive. Many variations of embodiments may become apparent to those skilled in the art upon review of the disclosure. The scope embodiments should, therefore, be determined not with reference to the above description, but instead should be determined with reference to the pending claims along with their full scope or equivalents.

The microfluidic system may be used in various applications, including but not limited to, biological, chemical, gas-phase reaction, or diagnostic assays and method thereof.

One or more features from any embodiment may be combined with one or more features of any other embodiment without departing from the scope embodiments. A recitation of “a”, “an” or “the” is intended to mean “one or more” unless specifically indicated to the contrary. Recitation of “and/or” is intended to represent the most inclusive sense of the term unless specifically indicated to the contrary.

While the present disclosure may be embodied in many different forms, the drawings and discussion are presented with the understanding that the present disclosure is an exemplification of the principles of one or more inventions and is not intended to limit anyone embodiment to the embodiments illustrated.

The disclosure, in its broader aspects, is therefore not limited to the specific details, representative system and methods, and illustrative examples shown and described above. Various modifications and variations may be made to the above specification without departing from the scope or spirit of the present disclosure, and it is intended that the present disclosure covers all such modifications and variations provided they come within the scope of the following claims and their equivalents.

What is claimed is:

1. A microfluidic valve comprising:
an adhesive tape comprising:
a backing layer;
an adhesive layer; and
a liner layer; wherein the adhesive layer is sandwiched between the backing layer and the liner layer and being joining materials by surface bonding;
an outlet disposed at one end of a first microfluidic channel;
an inlet disposed at one end of a second microfluidic channel,
an wherein the inlet and the outlet are disposed in a proximity to each other,
an wherein the adhesive tape covers both the outlet and the inlet.

2. The microfluidic valve of claim 1, wherein the liner layer covers a determined portion of the adhesive layer such that the liner layer covers the inlet located at one end of the first microfluidic channel but not the outlet located at one end of the second microfluidic channel.

3. The microfluidic valve of claim 1, wherein the liner layer covers a predetermined portion of the adhesive layer such that the liner layer only covers both the inlet located at one end of the first microfluidic channel, the outlet located at one end of the second microfluidic channel and the surface in proximity to the inlet and the outlet.

4. A method comprising the steps of:
providing an adhesive tape covering an inlet disposed at one end of a first microfluidic channel and an outlet disposed at one end of a second microfluidic channel;
directing a fluid to the first microfluidic channel at the other end;
building up fluidic pressure at the inlet;
pushing a predetermined portion of the adhesive tape away from the inlet and the outlet thereby forming a pocket such that the inlet is in fluid communication with the outlet; and
directing the fluid to flow from the inlet to the outlet through the pocket.

5. The method of claim 4, wherein only the predetermined portion of the adhesive tape is pushed away from the inlet and the outlet and such predetermined portion is in proximity to the inlet and the outlet.

6. The method of claim 4, further comprising the step of disconnecting the fluid communication between the inlet and the outlet by applying pressure towards the microfluidic channel at the predetermined portion.

7. The method of claim 6, further comprising the step of reducing a pressure at the predetermined portion prior to the pushing step.
